(19) United States
(12) Patent Application Publication
(10) Pub. No.: US 2005/0140406 A1
(43) Pub. Date: Jun. 30, 2005

(54) Power-on reset device

(76) Inventors: Pierre Rizzo, Aix-en-Provence (FR); Christophe Moreaux, Simiane (FR)

Correspondence Address: JENKENS & GILCHRIST, PC, 1445 ROSS AVENUE, SUITE 3200, DALLAS, TX, 75202, US

(21) Appl. No.: 11/001,779

(22) Filed: Nov. 30, 2004

(30) Foreign Application Priority Data
Dec. 5, 2003 (FR) 03 14321

(51) Int. Cl. H03L 7/00

(52) U.S. Cl. 327/143

(57) ABSTRACT

A power-on reset device for an electronic circuit includes an output terminal for delivering a reset signal. The reset signal may be active or inactive as a function of a supply voltage. A comparison node is coupled to the output terminal by way of at least one inverter. A first current source assembly delivers a first current to charge or discharge the comparison node. The first current is dependent on the supply voltage and on a specified current value, and is at maximum equal to this specified value. A second current source assembly delivers a second current to discharge or charge the comparison node. This second current is substantially independent of the supply voltage.

### PRIORITY CLAIM

This application claims priority from French Application for Patent No. 03 14321 filed Dec. 5, 2003, the disclosure of which is hereby incorporated by reference.

### BACKGROUND OF THE INVENTION

1. Technical Field of the Invention

The present invention relates in a general manner to power-on reset or POR devices for electronic circuits. The invention more particularly relates to circuits supplied with a low supply voltage, especially contactless cards, such as RFID tags (the abbreviation standing for “Radio Frequency IDentification”). It may however find applications also in the field of contact-type cards, especially in respect of mobile telephony, payment cards, or any other electronic circuit characterized by low power consumption.

2. Description of Related Art

POR devices are used to delay the enabling of electronic circuits until their supply voltage has built up sufficiently. This avoids erratic operation of the circuits when the latter are insufficiently powered to operate normally.

When a supply voltage is fed to the electronic circuit, it is often desirable to maintain the circuit in a reset state while the voltage has not reached a sufficient level to ensure the proper running of all the functions of the circuit. In certain cases, the supply voltage increases relatively slowly until reaching a stable value, as during the movement of a contactless card towards an interrogation unit from which it receives its energy by telesupply. If the functions of the circuit are not reset, their normal running may not be guaranteed, and a malfunction or even damage are possible. The role of a POR device is therefore to deliver a signal to block the operation of the electronic circuit.

The typical shape of a POR signal is presented in FIG. 1. It follows the supply voltage ramp Vcc while the latter has not reached a threshold value Vs, which is dependent in particular on the minimum operating voltage of the various components of the electronic circuit. The POR signal is therefore different from zero, this signifying that it is in the active state and that consequently the electronic circuit is reset. It will be considered to be at the logic 1 level for convenience in the subsequent account. Once the supply voltage becomes higher than Vs, the POR signal becomes zero; the POR signal is said to be in the inactive state. In this state, it permits operation of the electronic circuit.

FIG. 2 shows a known embodiment of a POR device, in accordance with Patent EP 0831589 B1, the disclosure of which is hereby incorporated by reference. In this embodiment, the threshold Vs is generated by two transistors: an N-type MOS (or NMOS) transistor MNl diode-mounted as well as a native P-type MOS (or PMOS) transistor MP1, whose gate is connected to an earth (ground) terminal 3 raised to a reference potential GND. The two transistors are linked in series between a supply terminal 2 delivering the supply voltage Vcc on the one hand and the earth/ground terminal via a resistor R on the other hand. Three inverters INV1, INV2, INV3 are connected in series between the node common to the source of MP1 and the resistor R, on the one hand, and an output node 4 delivering the POR signal, on the other hand. A capacitor C is linked between the terminal 2 and the output of the first inverter INV1 (the closest to MP1). The threshold Vs is therefore the sum of the turn-on voltages of the two transistors as well as the voltage required to switch the inverter INV1. The resistor R maintains the potential at the input of the inverter INV1 at a zero value while Vcc is below Vs. The capacitor C imposes a coupling of the input of a second inverter INV2 to Vcc to ensure that the POR signal is identical to Vcc during the supply rise phase while avoiding any metastable state of the inverters INV2 and INV3.

This embodiment is relatively simple. However it has a few disadvantages that may prove to be crippling in certain applications. Specifically, the current consumed by this type of circuit is proportional to the supply voltage Vcc since:
I=(Vcc−VTN−VTP)/R,
where I is the current consumed and VTN and VTP are the turn-on voltages (source-drain voltage) of the transistors MN1 and MP1, respectively. The current consumed I is then of the order of magnitude of the current consumed by the electronic circuit itself. A value of R of a few MegaOhms is necessary to meet the constraints of low consumption in the applications envisaged. Now, such a value is incompatible with an on-silicon embodiment.

Moreover, this embodiment does not allow hysteresis, that is to say the voltage threshold causing the toggling of the POR signal from 1 to 0 is strictly equal to the voltage threshold causing its toggling from 0 to 1. However, when the supply voltage Vcc reaches the threshold voltage Vs, the POR signal falls to 0. The consumption of the circuit then tends to collapse the power supply temporarily, this possibly causing Vcc to go below Vs and consequently causing the POR signals to toggle to 1. In certain cases, changes of state of the POR signal, related to oscillations of the supply voltage Vcc, may arise before it stabilizes at 0, this possibly being prejudicial to the proper switching on of the circuit. Hysteresis could be generated by doubling up the circuit of FIG. 2 and by using a Schmitt trigger, as in certain known embodiments. It would however remain difficult to adjust the hysteresis thus generated, to obtain stable and well-defined threshold values. Moreover, the consumption of current would be doubled.

A reset device exhibiting hysteresis is disclosed in the document U.S. Pat. No. 5,612,642 which is incorporated by reference herein.

According to another problem, the circuits of the state of the art are suitable for supply voltage ramps that are fast with respect to the time constants of the device, as is the case for contact-type cards. Larger capacitors and resistors, and therefore occupying a larger space on the silicon, would be necessary in order to adapt these circuits to the slow supply voltage rises encountered with contactless cards.

Another problem with known reset circuits is the undefined state of the POR signal while the supply voltage Vcc is lower than the threshold voltage. Now, it is important that the state of the POR signal be determined as fast as possible when the tag enters the emission field of an interrogation unit.

A need accordingly exists for a POR device exhibiting low current consumption with respect to the electronic circuit current level. A need also exists for a POR device which allows for an easily adjustable and stable hysteresis. A need further exists to provide a POR signal whose state is defined quickly for slow supply voltage ramps of the type encountered in a contactless card.

### SUMMARY OF THE INVENTION

A solution to these problems has been found in the use of direct current generators and of a current mirror whose duplication factor is dependent on the supply voltage VCC so as to compare the current emanating from the mirror with a direct current having either a first value or a second value, so as to control the changes of state of the POR signal.

In accordance with an embodiment of the invention, a power-on reset device comprises an output terminal for delivering a reset signal, which may be active or inactive as a function of a supply voltage. A comparison node is coupled to the output terminal by way of at least one inverter. A first current source assembly delivers a first current so as to charge or discharge the comparison node, wherein the first current is dependent on the supply voltage and on a specified current value, and being at maximum equal to the said specified value. A second current source assembly delivers a second current so as to discharge or charge the comparison node, wherein the second current is substantially constant during supply voltage rise ramp or decrease ramp.

Thus, the active or inactive state of the reset signal is determined by the potential on the comparison node, which results from the reckoning of the first and second currents at the level of this node.

The reset device may advantageously comprise a current mirror supplied with the supply voltage and delivering the first current to the output of the comparison node. Such a layout requires few components, thereby limiting the space occupied on the silicon by the device. Furthermore, the current consumption is low.

Preferably, the current mirror comprises a first and a second MOS transistor of substantially the same size, that are mounted as a current mirror. The embodiment on silicon is then simpler.

Additionally, the second current preferably has a first value higher than the value of the first current when the reset signal is active, and a second value lower than the said value of the first current IP when the reset signal is inactive. This makes it possible to introduce hysteresis in respect of the changes of state of the reset signal.

### BRIEF DESCRIPTION OF THE DRAWINGS

A more complete understanding of the invention may be obtained by reference to the following Detailed Description and with reference to the accompanying drawings wherein:

FIG. 1 is a time chart of the POR signal for a known reset device;

FIG. 2 is a block diagram of a known reset device;

FIG. 3 is a detailed diagram of an embodiment of a reset device according to the invention; and

FIG. 4 is a time chart of the POR signal generated by the device of FIG. 3.

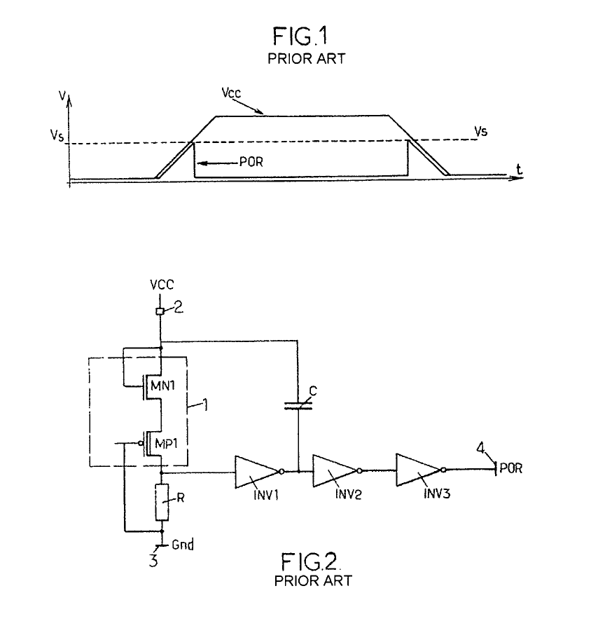

### DETAILED DESCRIPTION OF THE DRAWINGS

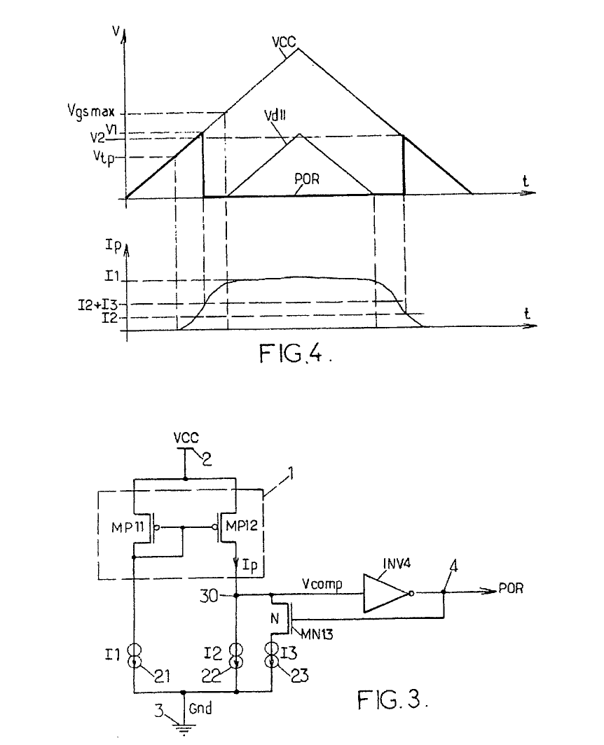

An exemplary embodiment of a reset device according to an embodiment of the invention is represented diagrammatically in FIG. 3. The circuit includes two PMOS transistors MP11 and MP12 respectively, mounted as a current mirror 1. They are of substantially the same size (i.e., they exhibit substantially the same ratio W/L) and are coupled by their source to the terminal 2 delivering the supply voltage Vcc. Their control gates are connected together, and to the drain of the transistor MP11. Three stable current sources bias the transistors MP11 and MP12 of the current mirror 1. A first current source CS1 21, delivering a current of value I1, biases the transistor MP11, by being disposed between its drain and the terminal 3 raised to the earth/ground potential GND. In what follows, all the voltages are referenced with respect to the earth/ground potential GND. Two current sources CS2 22 and CS3 23, delivering currents of value I2 and I3, respectively, bias the transistor MP11 by each being disposed between its drain and the terminal 3. The drain of the transistor MP12, corresponds to a node 30 which is referred to as the comparison node in what follows. In fact, the current source CS3 23 is connected in series with an NMOS transistor forming an on/off switch MN13, between the comparison node 30 and the earth/ground terminal 3.

The current source CS1 21 and the current mirror 1 form a first current source assembly, delivering a current Ip to charge the comparison node 30. The current Ip delivered to the comparison node 30 is a duplicate of the current I1, when Vcc is high enough to bias the transistors MP11 and MP12 to saturation. The two current sources CS2 22 and CS3 23 constitute a second current source assembly, which discharges the comparison node 30 with a current which equals I2+I3 (when the transistor MN13 is on) or with a current which equals I2 only (when the transistor MN13 is off).

The potential on the comparison node 30 is called Vcomp. This potential is substantially equal to Vcc (within the saturation voltage of the transistor MP11) when Ip>I2+I3, or to GND when Ip<I2+I3.

At least one inverter INV4 is coupled between the node 30 and the output terminal 4, which delivers the reset signal POR. Any odd number of inverters may be envisaged. The preferred embodiment of FIG. 3 provides for just one inverter. The transistor MN13 is controlled by the signal POR which it receives on its control gate.

The values of the currents I1, I2 and I3 are such that we have the following relation:
I1>I2+I3 (1)

FIG. 4 shows the shape of the POR signal as a function of the supply voltage Vcc, as well as the shape of the current Ip delivered by the first current source assembly. The voltage Vcc for the type of application envisaged (contactless card) is of the order of 1.5 to 2 V.

There are two threshold values for the toggling of the POR signal:
a first threshold value V1, which once overshot causes the POR signal to go from 1 to 0; and
a second threshold value V2, lower than the first value V1, which, once undershot, causes the POR signal to go from 0 to 1.

It will for example be possible to determine the value V2, as a function of the minimum supply voltages of the various components of the electronic circuit to be reset, and to fix V1 at a slightly higher value, calculated as a function of the expected value of the variations of the signal Vcc when the POR signal is deactivated.

The device represented in FIG. 3 operates as follows.

Initially, upon the entry of the tag into the emission field of an interrogation unit, the supply voltage Vcc is low. It is in particular lower than the operating threshold of the transistors MP11 and MP12, and the sources CS1 21, CS2 22 and CS3 23 have not yet built up to their steady values. The POR signal is then still undetermined. This is why it is desirable for the current sources to be adapted so as to operate as quickly as possible (i.e., for Vcc as low as possible) so as to allow the POR device to play its role of generating a reset signal in the active state.

Accordingly, the current sources CS1 21, CS2 22 and CS3 23 may be embodied for example in accordance with the work of G. Giustolisi, G. Palumbo, M. Criscione, and F. Cutri, presented in the article “A low voltage low power voltage reference based on Subthreshold MOSFETs”, published in the IEEE Journal of Solid State Circuits, vol. 38, n 1, January 2003, the disclosure of which is incorporated by reference. The current sources described therein use a PMOS transistor making it possible to deliver a constant reference voltage Vref as well as a reference current PTAT on the basis of a PMOS transistor. Duplicates of this reference current PTAT, on the basis of NMOS type transistors, make it possible to generate the current sources CS1 21, CS2 22 and CS3 23 for the device presented in FIG. 3.

There is a double benefit from this type of current source. On the one hand, the nominal strength of the current source is reached quickly during the supply voltage rise ramp. Specifically, the reference voltage and the constant current delivered are steady for low values of Vcc, thereby making the sources CS1 21, CS2 22 and CS3 23, and hence a specified state of the POR signal, available quickly. On the other hand, the total current consumed in the POR device is of the order of 500 nA, this being in a ratio 1:10 with respect to the prior art devices.

The POR signal is therefore in a specified state (the active state) for relatively low voltage values Vcc, that in any event are lower than the conduction threshold V_{TP} of the transistors MP11 and MP12. With such a value of Vcc, the drain/source voltage of the transistor MP11 is in this case equivalent to the gate/source voltage of this same transistor, and the duplicated current Ip is then zero. At the level of the comparison node 30, there is only the discharge current I2+I3, which maintains the potential Vcomp at the input of the inverter INV4 at a zero value. The reset signal POR is therefore at 1, thereby maintaining the on/off switch MN13 closed.

When the supply voltage Vcc grows and the conduction threshold V_{TP} is reached, the transistors MP11 and MP12 start to conduct. The current Ip delivered by the first current source assembly (CS1 21, MP11, MP12) rises until it reaches the value Ip=I1. When Ip exceeds the value Ip=I2+I3, which corresponds to the threshold V1 defined earlier, the voltage Vcomp on the comparison node 30 goes from the value 0 to substantially the value of the supply voltage Vcc, to within the drain source saturation voltage V_{DS}Sat of the transistor MP12. The signal POR goes to 0 as soon as Ip>I2+I3, by virtue of the inverter INV4. The feedback via the transistor MN13 then cuts off the current drawn on the comparison node 30 through the current source CS3 23. Only the current corresponding to the source CS2 22, of value I2, is then discharged from the comparison node 30. Since Ip was already higher than I2+I3, the signal POR is maintained at 0. Beyond, the supply voltage Vcc exceeds the maximum gate/source voltage Vgsmax of the transistor MP11, Ip is then substantially equal to I1.

The threshold value V1 for the toggling of the POR signal from 1 to 0 therefore corresponds to the value of the supply voltage Vcc when Ip reaches the value I2+I3.

When the supply voltage Vcc decreases, the voltage Vcomp at the input of the inverter INV4 follows Vcc. The current Ip decreases as soon as the supply voltage becomes substantially lower than the voltage Vgsmax of the transistor MP11. The signal POR is initially at 0, and remains so as long as the current Ip is higher than I2. When Ip reaches I2, the current drawn on the comparison node 30 is then bigger than the current Ip injected onto this node. Vcomp then goes to 0 and the POR signal toggles to 1. The feedback through the transistor MN13 again switches the reference current I3 generated by the current source CS3 23 on the basis of the comparison node 30. The value of the discharge current is again equal to I2+I3.

The voltage value V2 defined above for the threshold for toggling the POR signal from 0 to 1 therefore corresponds to the value of the supply voltage Vcc when Ip reaches the value I2.

Also represented in FIG. 4 is the variation of Vd11, the potential of the drain of the transistor MP11.

A further benefit of the device proposed by the invention is that it also allows proper supervision of the thresholds of the hysteresis. Specifically, to adjust this hysteresis, the value of the current I3 delivered by the current source CS3 23 is made to vary, which determines the difference V1−V2 (i.e., the difference in current between the high and low toggling points). By changing the W/L ratio of the transistor used for duplicating the reference current PTAT emanating from the work of Giustolisi et al., to increase the value of I3, it is thus possible to vary the difference between V1 and V2. A possible embodiment consists, for example, in using the ratios W/L, W/2L and W/4L respectively for the transistors used for duplicating the reference current PTAT emanating from the work of Giustolisi et al., this leading to the ratio 1:1, 1:0.5 and 1:0.25 respectively between the currents generated by the sources CS1 21, CS2 22 and CS3 23, and ensuring the condition posed by relation (1) above.

The circuit as proposed also allows tailoring of the thresholds V1 and V2 of the hysteresis, it is for example possible to vary the sizes W/L of the transistors MP11 and MP12 of the current mirror 1. Specifically, by increasing W/L, the saturation voltage Vdsat of the transistors will be reduced, and this will lead to a faster rise of the current Ip delivered by the current mirror 1, inducing a drop in the threshold values V1 and V2.

Since the threshold voltages of the various transistors used for the reset device (MP11, MP12, MN13, transistors for duplicating the reference current PTAT) can be supervised accurately during manufacture, the toggling thresholds of the POR signal can be accurately set.

The device illustrated by FIG. 3 is not the only possible embodiment. It is in particular possible to envisage a dual device, embodied on the basis of a current mirror using NMOS transistors and discharging the comparison node for comparing a current value Ip, dependent on the supply voltage Vcc and on the current source CS1 21, with a maximum value of I1. The two current sources CS2 22 and CS3 23 then charge the comparison node, which is itself coupled to the output terminal via an even number of inverters in series. The reference current PTAT proposed in the work of Giustolisi et al., is then used for example directly for each current source of the dual circuit mentioned earlier.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

1. A power-on reset device, comprising:
an output terminal for delivering a reset signal, which may be active or inactive as a function of a supply voltage;
a comparison node coupled to the said output terminal by way of at least one inverter;
a first current source assembly delivering a first current, so as to charge or discharge the comparison node, the first current being dependent on the supply voltage and on a specified current value, and being at maximum equal to the specified value; and
a second current source assembly, delivering a second current so as to discharge or charge the comparison node, the second current being substantially constant during supply voltage rise ramp or decrease ramp.

2. The device according to claim 1, wherein the first current source assembly comprises a current mirror supplied with the supply voltage, and delivering the first output current to the comparison node.

3. The device according to claim 2, wherein the current mirror comprises a first and a second MOS transistor of substantially the same size, that are mounted as a current mirror.

4. The device according to claim 1, wherein the second current has a first value higher than a value of the first current when the reset signal is active, and a second value lower than the value of the first current when the reset signal is inactive.

5. The device according to claim 3, wherein the first current is a charging current and the second current is a discharge current of the comparison node, and in which the comparison node is coupled to the output terminal via an odd number of inverters.

6. The device according to claim 5, wherein the first and second MOS transistors are P-type MOS transistors.

7. The device according to claim 3, wherein the first current is a discharge current and the second current is a charging current of the comparison node, and in which the comparison node is coupled to the output terminal via an even number of inverters.

8. The device according to claim 7, in which the first and second MOS transistors are N-type MOS transistors.

9. The device according to claim 1, wherein the second current source assembly comprises at least one first and one second current source mounted in parallel between the comparison node and earth/ground, the second source CS3 being coupled to the output terminal by an on/off switch (MN13) controlled by the reset signal in such a way as to be closed when the latter is active.

10. A circuit, comprising:
an inverter having an input and an output;
a first circuit to supply a first current to the inverter input;
a second circuit having a first mode of operation to drain a second current from the inverter input and a second mode of operation to drain a third current, greater than the second current, from the inverter input, a selection between the first and second modes of operation being controlled by the inverter output.

11. The circuit of claim 10 wherein the first circuit comprises a current mirror coupled to a supply voltage and configured to supply the first current dependent on the supply voltage.

12. The circuit of claim 10 wherein the second circuit includes a switch coupled to the inverter input and controlled by the inverter output, wherein the switch, when activated, places the second circuit in the second mode of operation to drain the third current.

13. The circuit of claim 12 wherein the switch, when deactivated, places the second circuit in the first mode of operation to drain the second current.

14. A circuit, comprising:
an inverter circuit having an input and an output;
a first current supply delivering a first current to the inverter circuit input, the first current supply being coupled to a voltage supply and the first current being dependent on the voltage supply; and
a second current supply delivering a second current to the inverter circuit input, the second current being substantially independent of the voltage supply.

15. The circuit of claim 14 wherein the first current supply charges the inverter circuit input with the first current and the second current supply discharges the inverter circuit input with the second current.

16. The circuit of claim 14 wherein the second current comprises a fixed current and a switched current.

17. The circuit of claim 16 wherein the second current supply further includes a switch circuit to selectively switch the switched current into and out of the second current.

18. The circuit of claim 17 wherein the switch circuit operates to selectively switch responsive to the inverter circuit output.

19. The circuit of claim 14 wherein the second current exceeds the first current when the inverter circuit output is active and does not exceed the first current when the inverter circuit output is inactive.

20. The circuit of claim 14 wherein inverter circuit comprises an odd number of individual inverters.

21. A circuit, comprising:
an inverter circuit having an input and an output;
a first circuit to deliver a first current to the inverter circuit input;
a second circuit having a first mode of operation to deliver a second current to the inverter circuit input and a second mode of operation to deliver a third current, different than the second current, to the inverter circuit input, a selection between the first and second modes of operation being controlled by the inverter circuit output.

22. The circuit of claim 21 wherein the first current is supplied to charge the inverter circuit input and the second and third currents are drained to discharge the inverter circuit input.

23. The circuit of claim 21 wherein the inverter circuit includes an odd number of inverters.

24. The circuit of claim 21 wherein the first circuit comprises a current mirror coupled to a supply voltage and configured to deliver the first current dependent on the supply voltage.

25. The circuit of claim 21 wherein the second circuit includes a switch coupled to the inverter circuit input and controlled by the inverter circuit output, wherein the switch, when activated, places the second circuit in the second mode of operation.

26. The circuit of claim 25 wherein the switch, when deactivated, places the second circuit in the first mode of operation
